(19) United States
(12) Patent Application Publication
(10) Pub. No.: US 2007/0046337 A1
(43) Pub. Date: Mar. 1, 2007

(54) Comparator circuit and semiconductor apparatus

(75) Inventor: Hiroyuki Kuge, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION

(21) Appl. No.: 11/510,749

(22) Filed: Aug. 28, 2006

(30) Foreign Application Priority Data
Aug. 30, 2005 (JP) 2005-250031

(51) Int. Cl. H03K 5/22

(52) U.S. Cl. 327/65

(57) ABSTRACT

A comparator circuit includes a first and a second PMOS transistors having sources connected to a first power supply and drains connected to a first node, NMOS transistors having sources connected to a second power supply and drains connected to the first node, a third and a fourth PMOS transistors having sources connected to the first power supply and the drains connected to a second node, and a third and a fourth NMOS transistors having sources connected to the second power supply and drains connected to the second node. A reference voltage and a voltage of a signal to be compared against are applied to gates of the thirst and the third PMOS transistors, and gates of the first and the third NMOS transistors. A comparator unit 1 outputs a comparison result between voltage of the first and the second nodes.

### BACKGROUND OF THE INVENTION

1. Field of the Invention

The present invention relates to a semiconductor apparatus, and particularly to a comparator circuit used in an input circuit.

2. Description of Related Art

In recent years, a signal transmission method with small amplitude has been adopted as a high-speed interface. For example there are various circuits for HSTL (High Speed Transceiver Logic) and SSTL (Stub Terminated Transceiver Logic) as JEDEC standard. An input circuit of such an interface includes a comparator (comparator circuit) for receiving a signal with small amplitude.

A comparator circuit using a differential circuit is widely known in the art. FIG. 9A is a circuit diagram showing a common comparator circuit.

As shown in FIG. 9A, a conventional comparator circuit 91 is comprised of PMOS transistors MP91 and MP92, and NMOS transistors MN91, MN92, and MN93. Characteristics of the transistor MP91 are the same as those of the MP92. Similarly characteristics of the MN91 are the same as those of the MN92. Sources of the transistors MP91 and the MP92 are connected to a power supply (VDD). Gates of the transistors MP91 and MP92 are commonly connected to a drain of the MP91. A drain of the transistor MN91 is connected to a drain of MP91, and a gate of the transistor MN91 is connected to an input terminal IN1, which is applied with a positive input signal (VIN1). A drain of the transistor MN92 is connected to a drain of the MP92. A gate of the MN92 is connected to an input terminal IN2, which is applied with a negative input signal (VIN2). Sources of the transistors MN91 and MN92 are commonly connected to a node N1. A drain of the transistor MN93 is connected to the node N1. A gate of the transistor MN93 is applied with a certain bias voltage (VBIAS), and a source is connected to ground (GND). An output from the comparator circuit 91 is obtained from a drain of the transistor MP91 or MP92. FIG. 9A shows a comparator circuit where an output (VOUT) obtained from the drain side of the transistor MP92 is outputted from the output terminal OUT. An output OUT is a positive output.

FIG. 9B shows an input/output characteristic of the comparator circuit 91. FIG. 9B illustrates a relationship between a difference of VIN1 and VIN2 (VIN1−VIN2) and an output level (VOUT). The comparator circuit 91 outputs 0 (“L”) if VIN1 is far lower than VIN2. On the other hand if VIN1 is far higher than VIN2, the comparator circuit 91 outputs VDD (“H”). In this circuit, a differential signal may be provided to IN1 and IN2, or as with a comparator circuit 92 of FIG. 9C, a reference voltage (VREF) may be supplied to one side, and an input signal (VIN) may be supplied to another side. If the input signal (VIN) is higher than the VREF level, an output level (VOUT) from the comparator circuit 92 is a low-level (“L”), whereas if the input signal (VIN) is lower than the VREF level, the output level (VOUT) from the comparator 92 is a high-level (“H”).

A comparator circuit 12 shown in FIG. 12 is disclosed in Japanese Unexamined Patent Application Publication No. 5-164791. The comparator circuit 12 disclosed in Japanese Unexamined Patent Application Publication No. 5-164791 lets a positive input voltage VP and a negative input voltage VN of a differential comparator circuit generate offsets based on resistance values so as to evaluate whether a difference of differential signals is more than or equal to a specified value.

As shown in FIG. 13, in a data transmission apparatus disclosed in Japanese Unexamined Patent Application Publication No. 11-068855, a resistance R131 and a resistance R132 are connected between a positive input node N131 of an input differential receiver circuit 131, the power supply (VDD), and the ground (VND). The apparatus further includes a resistance R133 and a resistance R134 connected to a negative input node N132.

In a conventional comparator circuit shown in FIGS. 9A and 9C, if a voltage of a power supply and ground to be supplied to the comparator circuit fluctuates due to noise, response time of the comparator circuit fluctuates correspondingly. An operation of a comparator circuit 92 in a case the voltage of the power supply (VDD) and the ground (GND) fluctuate is described hereinafter in detail. FIGS. 10A and 10B indicate an output VOUT in a case an input signal VIN is inputted to the comparator circuit 92. In FIGS. 10A and 10B, it is assumed that the reference voltage VREF and the input signal VIN are supplied from a circuit with a constant power supply (VDD) and the ground (GND) voltage. FIG. 10A illustrates a case where there is no fluctuation in the voltage of the power supply (VDD) and the ground (GND) of the comparator circuit 92. FIG. 10B illustrates a case where there is fluctuation in the voltage of the power supply (VDD) and the ground (GND) of the comparator circuit 92.

As shown in FIG. 10A, in a conventional comparator circuit, the output VOUT changes according to a change in the input signal VIN. A certain response time is needed from a change of the input signal VIN to a change of the output signal VOUT. The case in FIG. 10A is under an ideal condition where there is no fluctuation in the power supply (VDD) and the ground (GND). Accordingly the response time does not fluctuate. If the voltage of the power supply (VDD) and the ground (GND) of the comparator circuit 92 fluctuate due to noise, the relationship between the reference voltage VREF and the ground (GND) changes accordingly. Further, a potential difference (voltage difference) between the input voltage VIN and the ground (GND) fluctuates according to a fluctuation in power supply. The fluctuation in the potential difference causes a fluctuation in a timing that the output VOUT of the comparator circuit changes. As a result, response time of the comparator circuit 92 fluctuates due to the noise in the power supply (VDD) and the ground (GND) of the comparator circuit.

FIG. 11 is a view showing changes of the reference voltage VREF and the input signal VIN to the ground (GND) of the comparator circuit 92 from time t1 to t2 in FIGS. 10A and 10B. V and V′ show a change in the reference voltage VREF to the ground (GND). U and U′ show a change in the input signal VIN to the ground (GND). In FIG. 11, the solid lines indicate the voltages where no fluctuation exists in the voltages of the power supply (VDD) and the ground (GND) of the comparator circuit 92. The dashed lines indicate the voltages where there is fluctuation in the voltages of the power supply (VDD) and the ground (GND). In the same manner as in FIGS. 10A and 10B, it is assumed that the reference voltage VREF and the input signal VIN are supplied from a circuit with a constant power supply (VDD) and the ground (GND) voltage. As shown in FIG. 11, fluctuations in the voltages of the power supply (VDD) and the ground (GND) of the comparator circuit 92 relatively causes a fluctuation in the voltage the reference voltage and the input signal are inputted thereto (see U′ and V′ in FIG. 11). The fluctuation in the input of the comparator circuit causes a fluctuation in the response time of an output from the comparator circuit 92 for the change in input voltage VIN. Noise in the power supply and the ground of the comparator circuit 92 induces a delay fluctuation (jitter). The explanation above concerning the comparator circuit 92 also applies to the comparator circuit 91.

Furthermore in the comparator circuits 91 and 92, characteristics of the NMOS transistors (MN91 and MN92) comprising a transistor pair could fluctuate depending on a semiconductor apparatus (chip) due to production tolerance. For example if a threshold of the MN91 and MN92 increases, response of the comparator circuit delays. If the threshold of the MN91 and MN92 decreases, response of the comparator circuit speeds up. The production tolerance variations cause a fluctuation in circuit characteristics (delay) of the comparator circuits 91 and 92. In such a comparator circuit, response time to output for the input signal of the comparator circuit varies depending on a comparator circuit mounted to a semiconductor apparatus. In this example NMOS transistors are used to form a transistor pair. However even in a case the transistor pair is comprised of PMOS transistors, the production tolerance variations could cause the response time to output for the input signal of the comparator circuit to change.

As shown in FIG. 12, a comparator circuit (a differential voltage comparator circuit 12) disclosed in Japanese Unexamined Patent Application Publication No. 5-164791 includes resistors (R123, R124, R127, and R128) for each of positive input terminal and negative input terminal in a conventional comparator circuit (the comparator circuit 91 in FIG. 9). The comparator circuit 12 induces to generate offsets based on resistance values of the resistors to evaluate whether a difference in differential signals are more than or equal to a specified value. In the comparator circuit 12 disclosed in Japanese Unexamined Patent Application Publication No. 5-164791, characteristics of the NMOS transistors (MN121 and MN122) that form a transistor pair could fluctuate depending on a semiconductor apparatus (chip) due to production tolerance variations. Accordingly response time to output for the input signal of the comparator circuit could change depending on a comparator circuit mounted to a semiconductor apparatus.

Furthermore in the input differential receiver circuit 131 disclosed in Japanese Unexamined Patent Application Publication No. 11-068855, the positive input node N131 is also connected to an output driver circuit. Thus the input differential receiver circuit 131 is influenced by power supply and ground of the output driver circuit, although the negative input node N132 is not influenced. Therefore there is a difference in the ways the positive input node N131 and the negative input node N132 are influenced by the power supply and the ground fluctuation. There is no description regarding an internal circuit of the input differential receiver circuit 131 in Japanese Unexamined Patent Application Publication No. 11-068855. However if the internal circuit is configured in the similar manner as the comparator circuit 91 of a conventional technique, response time to output for an input signal of the comparator circuit could vary depending on a comparator circuit mounted to a semiconductor apparatus due to production tolerance.

As described in the foregoing, it has now been discovered that in a conventional comparator circuit, a fluctuation is generated in the response time to output for the input signal of the comparator circuit.

### SUMMARY OF THE INVENTION

According to an aspect of the present invention, there is provided a comparator circuit that includes a differential circuit having a transistor pair comprised of PMOS transistors or NMOS transistors with their sources connected to each other, a first PMOS transistor having a source connected to a first power supply, a drain connected to a first node, and a gate connected to a reference voltage input terminal, a first NMOS transistor having a source connected to a second power supply, a drain connected to the first node, and a gate connected to the reference voltage input terminal, a second PMOS transistor having a source connected to the first power supply, a drain connected to the first node, and a gate applied with a voltage of the second power supply, a second NMOS transistor having a source connected to the second power supply, a drain connected to the first node, and a gate applied with a voltage of the first power supply, a third PMOS transistor having a source connected to the first power supply, a drain connected to a second node, and a gate connected to a signal input terminal, a third NMOS transistor having a source connected to the second power supply, a drain connected to the second node, and a gate connected to a signal input terminal, a fourth PMOS transistor having a source connected to the first power supply, a drain connected to the second node, and a gate applied with a voltage of the second power supply, and a fourth NMOS transistor having a source connected to the second power supply, a drain connected to the second node, and a gate applied with a voltage of the first power supply. The first and the second power supplies are supplied to the differential circuit, one of the transistors forming the transistor pair includes a gate connected to the first node, and another transistor forming the transistor pair includes a gate connected to the second gate, and the differential circuit outputs a comparison result between a voltage of a signal inputted to the signal input terminal and a reference voltage applied to the reference voltage input terminal as a comparison result between a voltage value of the first node and a voltage value of the second node.

According to another aspect of the present invention, there is provided a semiconductor apparatus having a reference voltage generation circuit and a comparator circuit that includes a differential circuit having a transistor pair comprised of PMOS transistors or NMOS transistors with their sources connected to each other, a first PMOS transistor having a source connected to a first power supply, a drain connected to a first node, and a gate connected to a reference voltage input terminal, a first NMOS transistor having a source connected to a second power supply, a drain connected to the first node, and a gate connected to the reference voltage input terminal, a second PMOS transistor having a source connected to the first power supply, a drain connected to the first node, and a gate applied with a voltage of the second power supply, a second NMOS transistor having a source connected to the second power supply, a drain connected to the first node, and a gate applied with a voltage of the first power supply, a third PMOS transistor having a source connected to the first power supply, a drain connected to a second node, and a gate connected to a signal input terminal, a third NMOS transistor having a source connected to the second power supply, a drain connected to the second node, and a gate connected to a signal input terminal, a fourth PMOS transistor having a source connected to the first power supply, a drain connected to the second node, and a gate applied with a voltage of the second power supply, and a fourth NMOS transistor having a source connected to the second power supply, a drain connected to the second node, and a gate applied with a voltage of the first power supply. The first and the second power supplies are supplied to the differential circuit of the comparator circuit, one of the transistors forming the transistor pair includes a gate connected to the first node, and another transistor forming the transistor pair includes a gate connected to the second gate, the differential circuit outputs a comparison result between a voltage of a signal inputted to the signal input terminal and a reference voltage applied to the reference voltage input terminal as a comparison result between a voltage value of the first node and a voltage value of the second node, and the reference voltage generation circuit operates on a third and a fourth power supply that are different from the first and the second power supplies.

According to another aspect of the present invention, there is provided a comparator circuit that include a comparator unit connected between a first power supply and a second power supply, a first noise tracing unit for inputting a first signal based on a first input signal to the comparator unit, and connected between the first power supply and the second power supply and a second noise tracing unit for inputting a second signal based on a second input signal to the comparator unit, and connected between the first power supply and the second power supply.

The circuit formed as above enables to reduce fluctuation in response time to output for the input signal of the comparator circuit, which is caused by a fluctuation in power supply or ground voltage of the comparator circuit due to noise. Furthermore, the circuit allows to reduce fluctuation in response time to output for the input signal of the comparator circuit due to production tolerance.

The present invention enables to reduce a fluctuation in response time to output for an input signal of a comparator circuit.

### BRIEF DESCRIPTION OF THE DRAWINGS

The above and other objects, advantages and features of the present invention will be more apparent from the following description taken in conjunction with the accompanying drawings, in which:

FIG. 1 is a circuit diagram showing a comparator circuit according to a first embodiment of the present invention;

FIG. 2 is a view showing an input/output characteristic of a noise tracing unit;

FIG. 3 is a view showing voltages of each section in a comparator circuit;

FIGS. 4A and 4B are views showing input/output characteristics of a noise tracing unit;

FIG. 5 is a view showing voltage of each section in a comparator circuit;

FIG. 6 is a view showing a transition of a voltage supplied to a NMOS transistor of a comparator unit 1;

FIG. 7 is a circuit diagram showing a variation of the comparator circuit of the first embodiment;

FIG. 8 is a circuit diagram showing a comparator circuit according to a second embodiment of the present invention;

FIGS. 9A to 9C are circuit diagrams showing a comparator circuit according to a conventional technique;

FIGS. 10A and 10B are views showing voltages of each section of a comparator circuit according to a conventional technique;

FIG. 11 is a view showing a transition of a voltage supplied to a NMOS transistor in a comparator circuit according to a conventional technique;

FIG. 12 is a circuit diagram showing a comparator circuit according to a conventional technique;

FIG. 13 is a circuit diagram showing an input differential receiver circuit according to a conventional technique;

FIG. 14 is a circuit diagram showing a variation of the comparator circuit of the second embodiment; and

FIG. 15 is a circuit diagram showing a variation of the comparator circuit of the second embodiment.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

A first embodiment of the present invention is described hereinafter in detail with reference to the drawings. In a comparator circuit of this invention, a reference voltage VREF is inputted to an input terminal (hereinafter referred to as a reference voltage input terminal), and a signal VIN outputted by a previous circuit, for example, to be compared against is inputted to another input terminal (hereinafter referred to as a signal input terminal). A comparator circuit of this embodiment is formed on a chip as a semiconductor integrated circuit, for example. A reference voltage generation circuit for supplying a reference voltage is formed on the same chip.

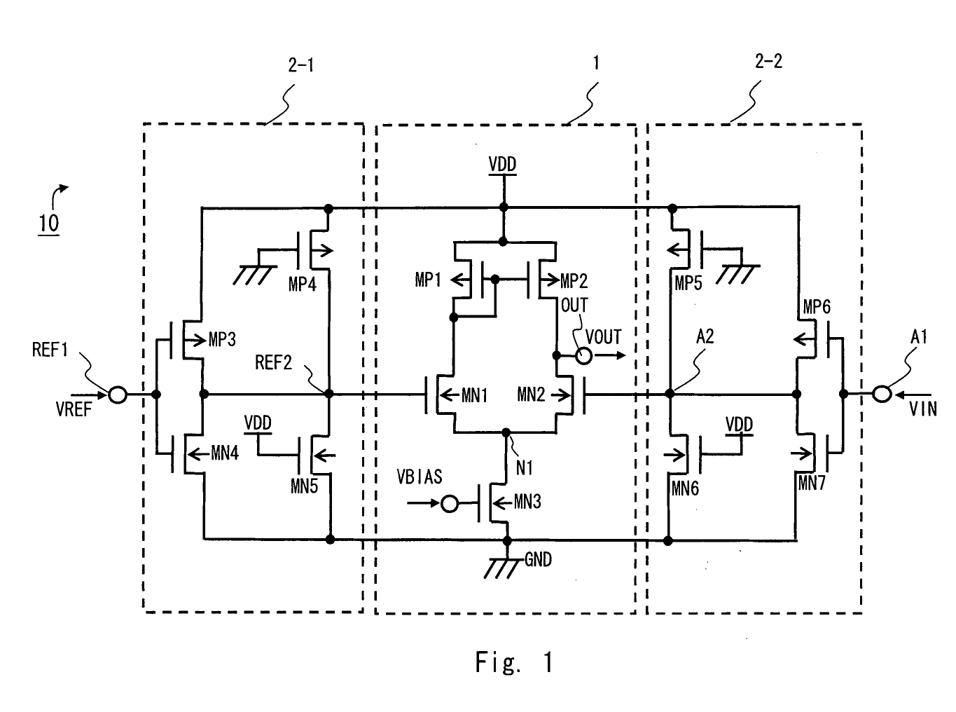

FIG. 1 is a view showing a comparator circuit of the first embodiment. A comparator circuit 10 of this embodiment includes a comparator unit 1, noise tracing units 2-1 and 2-2.

The comparator unit (differential circuit) 1 includes a PMOS transistors MP1 and MP2, and NMOS transistors MN1, MN2, and MN3. Sources of the transistors MP1 and MP2 are connected to a power supply VDD (a first power supply). Gates of the PMOS transistors MP1 and MP2 are connected to a drain of the transistor MP1. A drain of the PMOS transistor MP1 is connected to a drain of the NMOS transistor MN1. A drain of the PMOS transistor MP2 is connected to a drain of the NMOS transistor MN2. Sources of the NMOS transistors MN1 and MN2 are connected to a drain of the NMOS transistor MN3. A gate of the NMOS transistor MN1 is connected to an output node REF2 of the noise tracing unit 2-1. The noise tracing unit 2-1 is formed on a side of the reference voltage input terminal explained later in detail. A gate of the NMOS transistor MN2 is connected to an output node A2 of the noise tracing unit 2-2. The noise tracing unit 2-2 is formed on a side of the signal input terminal explained later in detail. The NMOS transistors MN1 and MN2 form a transistor pair to be a differential input unit of the comparator unit 1. A source of the NMOS transistor MN3 is connected to the ground GND (a second power supply). A bias voltage VBIAS (fixed voltage) is applied to a gate of the NMOS transistor MN3. The NMOS transistor MN3 is connected as a constant current source.

The noise tracing unit 2-1 is provided to the side of the reference voltage input terminal (terminal REF1) and the noise tracing unit 2-2 is provided to the side of the signal input terminal (terminal A1). The noise tracing unit 2-1 on the side of the reference voltage input terminal includes PMOS transistors MP3 and MP4, and NMOS transistors MN4 and MN5. Sources of the PMOS transistors MP3 and MP4 are connected to the power supply VDD, the same power supply the comparator unit 1 is connected thereto. A gate of the PMOS transistor MP3 is connected to the reference voltage input terminal REF1, and a drain is connected to a drain of the NMOS transistor MN4. A gate of the PMOS transistor MP4 is connected to the ground GND, the same ground GND the comparator unit 1 is connected thereto. A gate of the NMOS transistor MN4 is connected to the reference voltage input terminal REF1. A gate of the NMOS transistor MN5 is connected to the power supply VDD, the same power supply the comparator unit 1 is connected thereto. Sources of the NMOS transistors MN4 and MN5 are connected to the ground GND, the same ground GND the comparator unit 1 is connected thereto. A node that drains of the PMOS transistors MP3 and MP4, and NMOS transistors MN4 and MN5 are connected thereto corresponds to an output node REF2 of the noise tracing unit 2-1. The PMOS transistor MP3 and the NMOS transistor MN4 form an inverter for amplifying the reference voltage. The PMOS transistor MP4 and NMOS transistor MN5 form a voltage divider for dividing the reference voltage.

The noise tracing unit 2-2 of the signal input terminal side includes PMOS transistors MP5 and MP6, and NMOS transistors MN6 and MN7. The noise tracing unit 2-2 of the signal input terminal side has the same configuration as the noise tracing unit 2-1 of the reference voltage input terminal side except for nodes an input and an output are connected thereto. Specifically the PMOS transistors MP5 and NMOS transistors MN6 are connected in series between the power supply VDD, which is the same power supply the comparator unit 1 is connected thereto, and the ground GND. A gate of the PMOS transistor MP5 is connected to the ground GND, and a gate of the NMOS transistor MN6 is connected to the power supply VDD. The PMOS transistor MP6 and the NMOS transistor MN7 are connected in series between the power supply VDD, which is the same power supply the comparator unit 1 is connected thereto, and the ground GND. The signal input terminal A1 is connected to gates of the PMOS transistors MP6 and MN7. A node that drains of the PMOS transistors MP5 and MP6 and drains of the NMOS transistors MN6 and MN7 are commonly connected thereto corresponds to the output node A2 of the noise tracing unit 2-2. The PMOS transistor MP6 and the NMOS transistor MN6 form an inverter for amplifying the input voltage. The PMOS transistor MP5 and NMOS transistor MN6 form a voltage divider for dividing the input voltage.

The output terminal OUT of the comparator circuit 10 of the first embodiment is a node between the PMOS transistor MP2 and the NMOS transistor MN2 of the comparator unit 1. The comparator circuit outputs “L” level (low-level) to the reference voltage VREF if a voltage VIN of a signal inputted to the signal input terminal is low, and outputs “H” (high-level) if the voltage VIN is high (hereinafter “low level” is referred to as “L”, while “high-level” is referred to as “H”). In the comparator circuit shown in FIG. 1, an inverted output to the output terminal OUT can be obtained from the node between the PMOS transistor MP1 and the NMOS transistor MN1 in the comparator unit 1.

The MOS transistors formed in the noise tracing units 2-1 and 2-2 are formed in the same process as the MOS transistors in the comparator unit 1. Specifically, the NMOS transistors MN4, MN5, MN6, and MN7 in the noise tracing units 2-1 and 2-2 are formed at the same time as the NMOS transistors MN1 and MN2 in the comparator unit 1. Therefore, a production tolerance among the NMOS transistors MN4, MN5, MN6, and MN7 can be ignored.

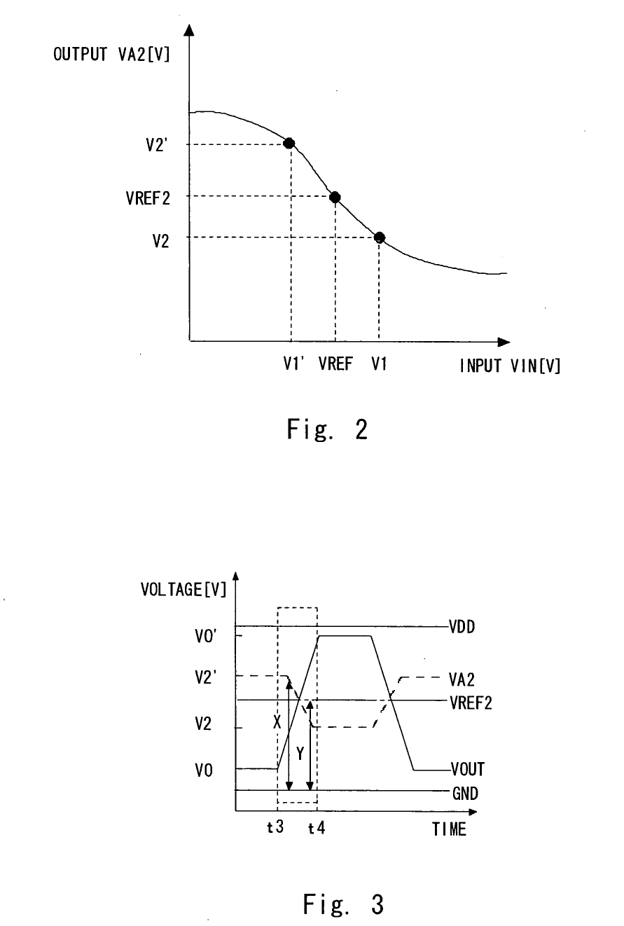

An operation of the comparator circuit 10 formed as above is described hereinafter in detail. A basic operation in a case there is no voltage fluctuation in the power supply VDD and the ground GND is described first. The reference voltage VREF is applied to the reference voltage input terminal REF1. The voltage VIN to be compared is applied to the signal input terminal A1. FIG. 2 is a view showing an input/output characteristic of an input voltage VIN for the signal input terminal A1 and a voltage VA2 of the node A2 in the noise tracing circuit 2-2. FIG. 3 is a view showing voltages of each unit in case of changing a level of a signal to be inputted to the signal input terminal A1 to “L”—“H”—“L” in this order.

In the following description of basic operation, the reference voltage VREF applied to the reference voltage input terminal REF1 is an intermediate voltage that makes the PMOS transistor MP3 and the NMOS transistor MN4 be semiconductive. In this case, the voltage VREF2 of the node REF2 is a voltage obtained by dividing a potential difference (voltage difference) between the power supply VDD and the ground GND by a parallel resistance of the PMOS transistors MP3 and MP4, and a parallel resistance of the NMOS transistors MN4 and MN5. Accordingly a specified voltage VREF2 based on the reference voltage VREF is applied to a gate of the NMOS transistor MN1 of the comparator unit 1.

At this time a voltage VgsN1 between a gate and a source of the NMOS transistor MN1 has a value obtained by subtracting an amount of voltage drop in the NMOS transistor MN3 from the voltage VREF2 that is supplied to the gate of the NMOS transistor MN1. To simplify the explanation, the NMOS transistor MN3 is hereinafter referred to as an ideal current source (resistance=0). Therefore the explanation assumes that the voltage between the gate and the source of the NMOS transistor MN1 equals to a gate voltage (potential) of the NMOS transistor MN1.

In the noise tracing circuit 2-2, the voltage VA2 of node A2 is obtained by dividing a potential difference (voltage difference) between the power supply VDD and the ground GND by a parallel resistance of the PMOS transistor MP5, and a parallel resistance of the NMOS transistors MN6 and MN7. A resistance value of the PMOS transistor MP6 and the NMOS transistor MN7 is determined according to a voltage of a signal inputted to the signal input terminal A1. Accordingly the voltage VA2 of the node A2 is determined according to the voltage VIN of a signal inputted to the signal input terminal A1.

Since the noise tracing circuit 2-2 is formed in the same manner as the noise tracing circuit 2-1, if an input voltage VIN that equals to the VREF is inputted to the signal input terminal A1, the voltage VA2 equals VREF2.

If the voltage VIN to be applied to the signal input terminal A1 is a voltage V1 (“H” level) that is higher than the reference voltage VREF, a resistance of the NMOS transistor MN7 is reduced and a resistance of the PMOS transistor MP6 increases in the noise tracing circuit 2-2. Accordingly a voltage drop of the PMOS transistor MP6 increases. Thus the voltage VA2 of the node A2 becomes V2, which is lower than VREF (see FIG. 2). This voltage V2 is supplied to a gate of the NMOS transistor MN2 in the comparator unit 1.

If the voltage applied to the input signal terminal A1 is a voltage V1′ (“L” level) that is lower than VREF, a resistance of the PMOS transistor MP6 is reduced and the resistance of the NMOS transistor MN7 increases. Accordingly a voltage drop of the PMOS transistor MP6 reduces. Thus the voltage VA2 of the node A2 becomes V2′, which is higher than VREF (see FIG. 2). This voltage V2′ is supplied to a gate of the NMOS transistor MN2 in the comparator unit 1.

As described in the foregoing, when changing the voltage VIN to be applied to the signal input terminal A1 to “L”—“H”—“L” (changing VIN to V1′—V1—V1′), the voltage VA2 of the node A2 changes to V2′—V2—V2′ as indicated with the dashed line in FIG. 3. If the voltage of the node A2 is V2′, meaning that the input voltage VIN is “L”, a current following to the PMOS transistor MP2 and the NMOS transistor MN2 increases. Consequently the comparator circuit output an “L” level signal, VO (see VOUT=VO in FIG. 3). If the voltage of the node A2 is low, meaning that the input voltage VIN is “H” level, a current flowing to the PMOS transistor MP2 and the NMOS transistor MN2 decreases. As a result the comparator circuit outputs an “H” level signal as VO′ (see VOUT=VO′ in FIG. 3).

An operation in a case where a fluctuation exists in the power supply and the ground of the comparator circuit is described hereinafter. In this embodiment, the abovementioned power supply of the reference voltage generation circuit operates on a separate and stable power supply that is independent from the power supply of the comparator circuit for generating a reference voltage. Thus the power supply of the reference voltage generation circuit in this embodiment does not fluctuate. Accordingly the reference voltage VREF applied to the reference voltage input terminal REF1 does not fluctuate but a voltage with a constant value is supplied. Furthermore in this embodiment, the signal applied to the signal input terminal A1 is outputted from a separate chip, for example, so that it is not influenced by a power supply fluctuation in the comparator circuit.

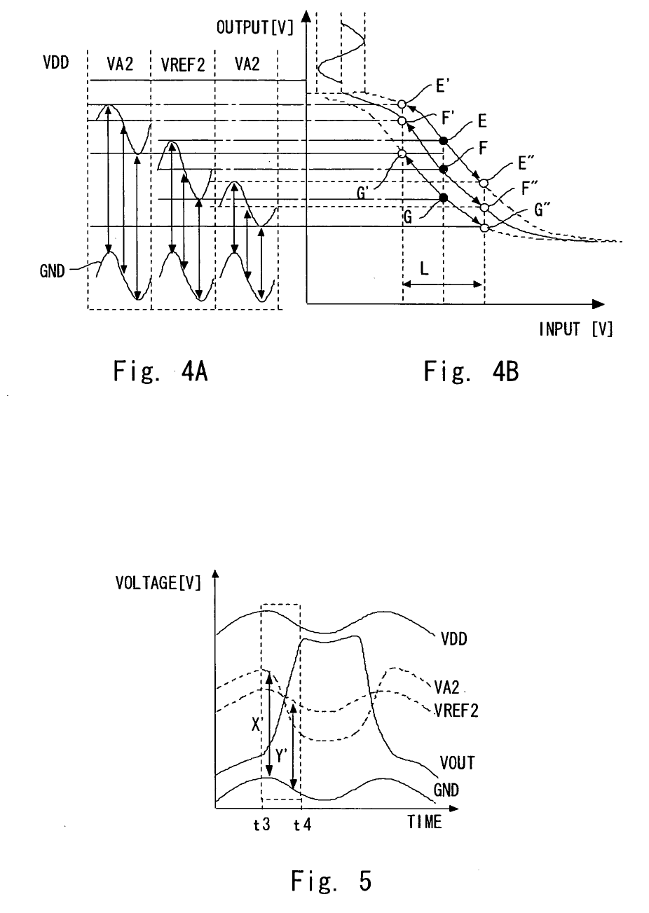

FIGS. 4A and 4B show waveforms of voltages outputted by the noise tracing circuits 2-1 and 2-2 in a case the power supply and the ground fluctuate. FIG. 4A indicates a fluctuation in voltage of the power supply and the ground, and a fluctuation in a voltage outputted by the noise tracing circuits 2-1 and 2-2. FIG. 4B shows input/output characteristics of the noise tracing circuits 2-1 and 2-2 in a case the power supply and the ground fluctuate. FIGS. 4A and 4B illustrate an example where the power supply VDD and the ground GND fluctuate together due to an influence of noise, for example. Specifically, the example shown in FIGS. 4A and 4B is a case where a fluctuation occurs in a way that the power supply VDD and the ground GND shift upward or downward.

The noise tracing circuit 2-1 of the reference voltage input side outputs a voltage to the output node REF2, where the voltage is obtained by dividing a potential difference (voltage difference) of the power supply VDD and the ground GND by the PMOS transistors MP3 and MP4, and the NMOS transistors MN4 and MN5. Therefore if the power supply or the ground fluctuates, the voltage of the output node REF2 fluctuates correspondingly (see the part for VREF2 in FIG. 4A).

The noise tracing circuit 2-2 of the signal input side outputs a voltage to the output node A2, where the voltage is obtained by dividing a potential difference (voltage difference) of the power supply VDD and the ground GND by the PMOS transistors MP5 and MP6, and the NMOS transistors MN6 and MN7. If the power supply VDD or the ground GND fluctuates, the voltage of the output node A2 fluctuates correspondingly (see FIG. 4A) However if a signal inputted to the signal input terminal A1 is “H” level, the noise tracing circuit 2-2 on the signal input side changes reflecting the fluctuation in the power supply and the ground with a center focused on the voltage V2. If the signal inputted to the signal input terminal A1 is “L” level, it changes reflecting the fluctuation in the power supply with a center focusing on the abovementioned voltage V2′.

In FIG. 4B, if the power supply is stable, a voltage of the output node REF2 is indicated by F, a voltage of the output node A2 when “L” level is inputted to the signal input terminal A1 is indicated by F′, and the voltage of the output node A2 when “H” level is inputted to the signal input terminal A1 is indicated by F″. As shown in FIGS. 4A and 4B, if the power supply VDD and the ground GND shift upward, voltages outputted by the noise tracing circuits 2-1 and 2-2 increase, accordingly the noise tracing circuits 2-1 and 2-2 output voltages indicated by E, E′ and E″ in FIG. 4B. If the power supply VDD and the ground GND shift downward, voltages outputted by the noise tracing circuits 2-1 and 2-2 decrease, accordingly the noise tracing circuits 2-1 and 2-2 output voltages indicated by G, G′ and G″ in FIG. 4B. In this embodiment, it is desirable that slopes of the input/output characteristics for the noise tracing circuit do not change and stay constant even if the power supply and the ground shift within an input range L to be inputted to the comparator circuit.

FIG. 5 is a view showing voltages of each section in the comparator circuit in a case a signal inputted to the signal input terminal A1 is changed to “L”—“H”—“L” if the power supply and the ground of a comparator circuit fluctuate. As shown in FIG. 5, the voltage supplied to the gate of the NMOS transistor MN1 (i.e. the voltage VREF2 of the output node REF2) fluctuates reflecting fluctuations in the power supply and the ground.

Furthermore, the voltage supplied to the gate of the NMOS transistor MN2 (the voltage VA2 of the output node A2) basically changes in order of high voltage (V2′)—low voltage (V2)—high voltage (V2′). The voltage supplied to the gate of the NMOS transistor MN2 further being superposed with the fluctuation in the power supply and the ground over the change (see FIG. 5).

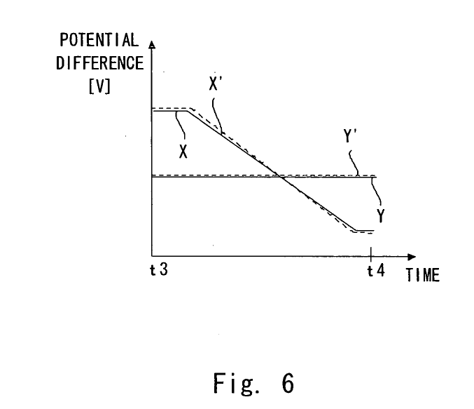

Thus with the comparator circuit of this embodiment, even if the power supply and the ground fluctuate, a voltage reflecting the fluctuation is supplied to the gates of the NMOS transistors MN1 and MN2 in the comparator unit 1. In this example as described in the foregoing, the NMOS transistor MN3 is assumed to be an ideal current source (resistance=0), and a voltage between the gate and the source of the NMOS transistor MN1 is assumed to equal the gate voltage of the NMOS transistor MN1. Accordingly FIG. 6 shows a voltage between gates and source (GND) of the NMOS transistors MN1 and MN2 in the comparator unit 1.

FIG. 6 is a view showing changes of the voltages VREF2 and VA2 to the ground (GND) of the comparator circuit 10 from time t3 to t4 in FIGS. 3 and 5. In FIG. 3, X shows a change in the voltage VA2 to the ground (GND), and Y shows a change in the reference voltage VREF2 to the ground (GND). In FIG. 5, X′ shows a change in the voltage VA2 to the ground (GND), and Y′ shows a change in the reference voltage VREF2 to the ground (GND). Therefore, in FIG. 6, the solid lines (X, Y) indicate the voltages where no fluctuation exists in the voltages of the power supply (VDD) and the ground (GND) of the comparator circuit 10. The dashed lines (X′, Y′) indicate the voltages where there is fluctuation in the voltages of the power supply (VDD) and the ground (GND).

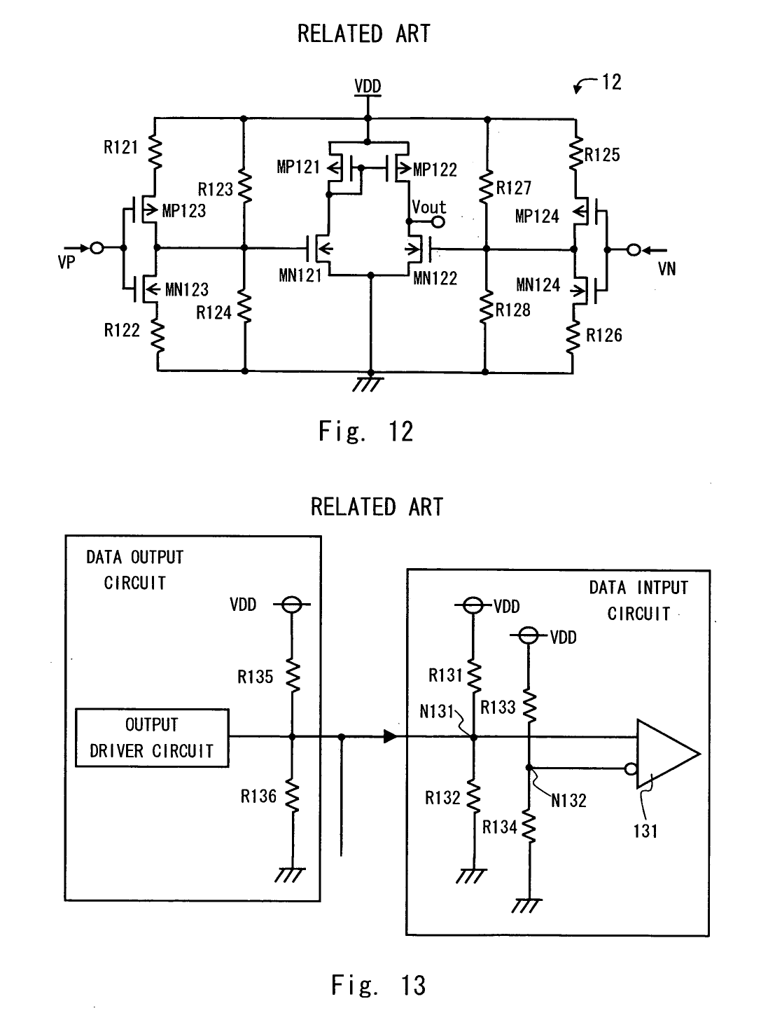

As obvious from FIG. 6, this embodiment enables to prevent a voltage between gate and source to be supplied to the NMOS transistors MN1 and MN2 from changing caused by the fluctuation in the power supply and the ground. With a conventional comparator circuit as shown in FIG. 11, a voltage between a gate and a source of a NMOS transistor where a reference voltage is inputted, and a voltage between a gate and a source of a NMOS transistor where a comparator voltage is inputted change along with a fluctuation in the power supply and the ground. With the circuit of this embodiment, gate voltages of the NMOS transistors MN1 and MN2 change reflecting a fluctuation in the power supply and the ground. Thus it is possible to suppress a fluctuation in response time caused by a fluctuation in the power supply and the ground.

Furthermore in this embodiment, the transistors MN5 and MN6 are NMOS transistors formed at the same time as the NMOS transistors in the comparator unit 1. If a threshold of the NMOS transistors MN1 and MN2 exceeds a target value, a switching speed of the comparator unit 1 delays. On the other hand, in a comparator circuit of this embodiment, the NMOS transistors MN5 and MN6 are formed at the same time as the NMOS transistors MN1 and MN2. Thereby, on-resistances of the NMOS transistors MN5 and MN6 become larger corresponding to threshold increase in the NMOS transistor MN1 and MN2. Accordingly voltage drops of the NMOS transistor MN5 and MN6 increases. Specifically, voltages of the output node REF2 and the output node A2 increase, accordingly gate voltages of the NMOS transistors MN1 and MN2 increases to speed up the switching speed.

Conversely if the threshold of a NMOS transistor decreases lower than a target value, a switching speed of the comparator unit 1 speeds up. Since the NMOS transistors MN5 and MN6 are formed at the same time as the transistor MN1 and MN2, on resistances of the NMOS transistors MN5 and MN6 decreases. Accordingly voltages of the output node REF 2 and the output node A2 decrease, thereby slowing down the switching speed. That is, by forming the NMOS transistors MN5 and MN6 at the same time as the NMOS transistors MN1 and MN2, it is possible to reduce fluctuation in response time caused by production tolerance variations.

In the circuit shown in FIG. 13, relatively large parasitic capacitance of a protection device and outside a chip is directly connected to the node N131. Therefore, to reduce fluctuation in response time to output for the input signal of the comparator circuit, the same level of capacity needs to be connected to the node N132 to conform an ability to trace the power supply and the ground fluctuation with the node N132. This causes to increase a circuit size. However in this embodiment, such a problem does not arise because transistors are mounted to input. Further in this embodiment, with the transistor mounted to input, there is no difference generated in influences from fluctuations in the power supply and the ground to the signal input terminal A1 and the reference voltage input terminal REF1.

The explanation referring to FIGS. 4 to 6 uses an example where both the power supply VDD and the ground shift because of noise. However the noise tracing circuit of this embodiment can be applied to a case where either of the power supply VDD or the ground GND fluctuates. For example if the power supply VDD fluctuates to VDD+ΔVDD due to noise, a change in voltages of the output node REF2 and the A2 is reduced by a resistance ratio of the NMOS transistor and the PMOS transistor. If on resistances of the NMOS transistors MN4 and MN5, and the PMOS transistors MP3 and MP4 are all equal, a change in the voltage of the output node REF2 is ΔVDD/2. Further, if on resistances of the NMOS transistor MN6 and the PMOS transistor MP5 are equal, a change in the voltage of the output node A2 is approximately ΔVDD/2, although it varies depending on the level inputted to the signal input terminal A1.

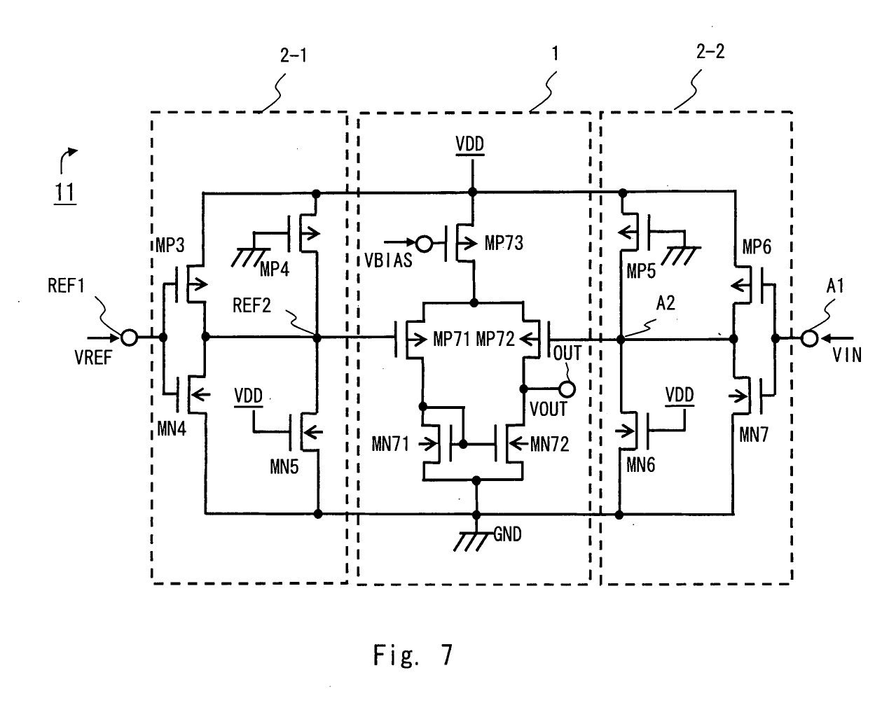

FIG. 7 is a view showing a variation of a comparator circuit of the first embodiment. A configuration of the comparator unit 1 of FIG. 7 is different from that of FIG. 1. In the circuit of FIG. 7, an output node REF2 of the noise tracing circuit 2-1 on the reference voltage input side is connected to a gate of a PMOS transistor MP71. An output node A2 of the noise tracing circuit 2-2 on the signal input side is connected to a gate of the PMOS transistor MP72. The NMOS transistors MN71 and MN72 form a current mirror, with gates commonly connected to a drain of the MN71. In this configuration, a PMOS transistor MP73 is a constant current source, connected between sources of the PMOS transistor MP71 and MP72, and the power supply VDD. A bias voltage VBIAS is supplied to a gate of the PMOS transistor MP73. In a circuit shown in FIG. 7, if a voltage inputted to the signal input terminal is higher than a reference voltage inputted to the reference voltage input terminal, the circuit outputs “H” level. Otherwise the circuit outputs “L” level. The circuit shown in FIG. 7 has NMOS transistors MN71 and MN72 instead of PMOS transistors MP1 and MP2 of the circuit of FIG. 1. The circuit shown in FIG. 7 has PMOS transistors MP71, MP72 and MP73 instead of NMOS transistors MN1, MN2 and MN3 of the circuit of FIG. 1. The operation of the circuit shown in FIG. 7 is basically the same as the circuit shown in FIG. 1 except for conduction type of transistors, thereby detailed explanation of the operation is omitted here. In the circuit of FIG. 7, as with the circuit of FIG. 1, by forming the PMOS transistors MP71 and MP72, and the PMOS transistors MP4 and MP5 at the same time, it is possible to restrain from fluctuation in response time, that is caused by production tolerance variations.

### Second Embodiment

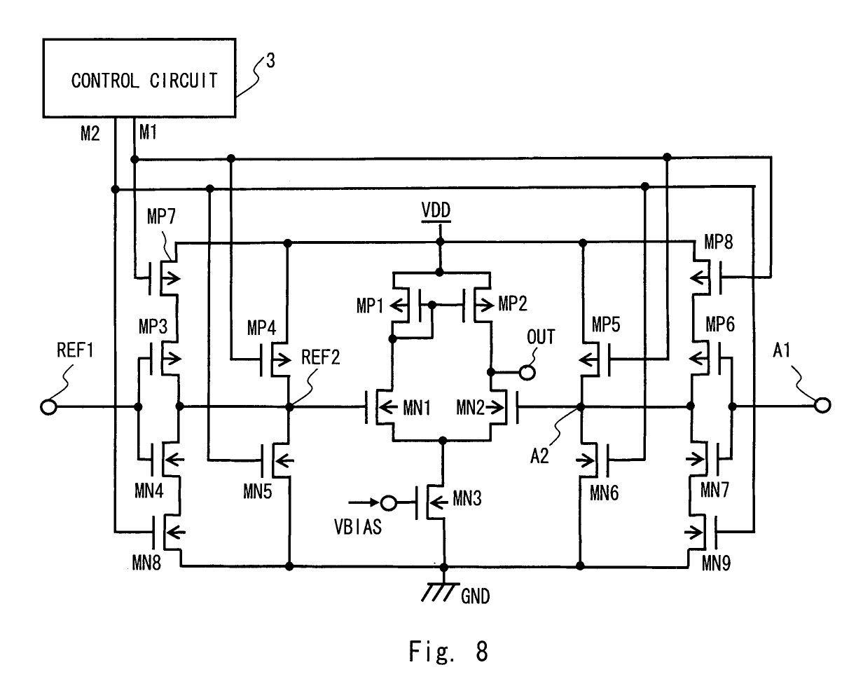

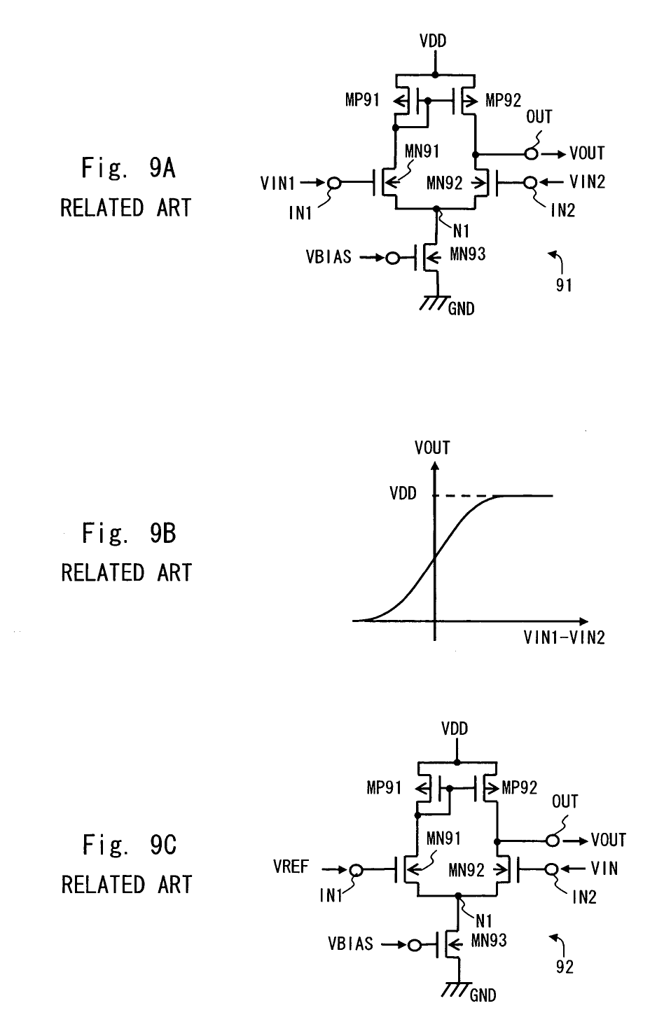

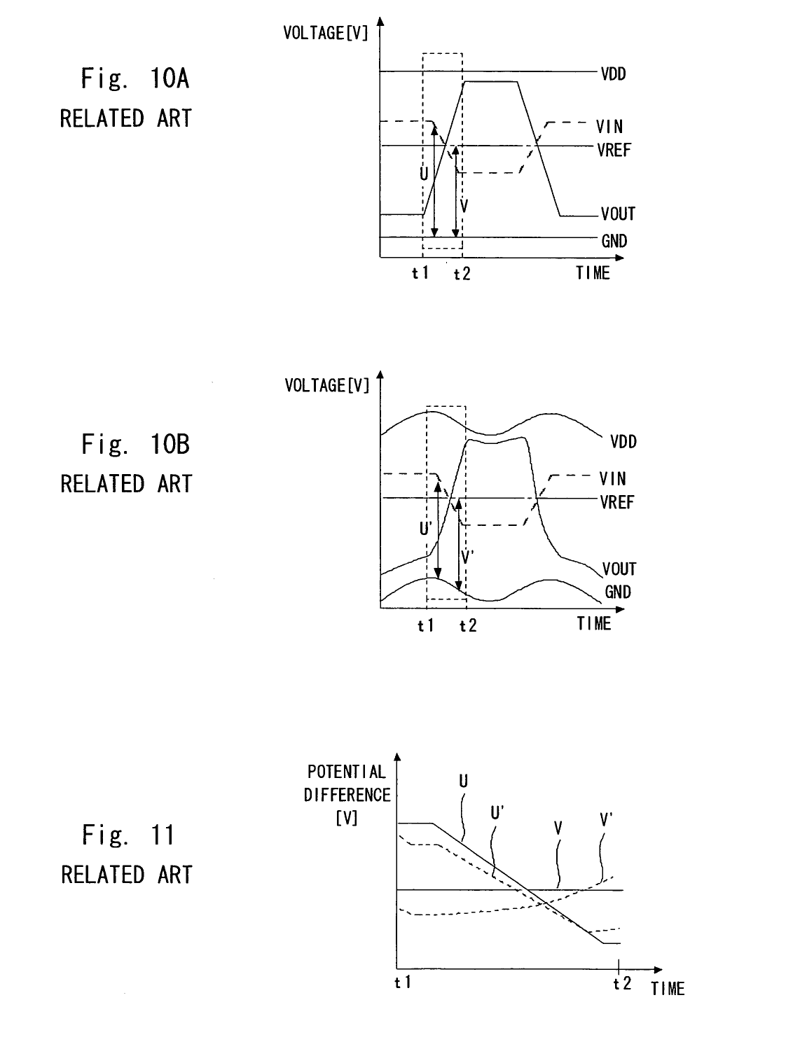

FIG. 8 is a circuit diagram showing a comparator circuit according to a second embodiment of the present invention. In FIG. 8, components identical to those in the first embodiment are denoted by reference numerals identical to those therein with detailed description omitted. The comparator circuit of this embodiment additionally includes PMOS transistors MP7 and MP8, and NMOS transistors MN8 and MN9, and a control circuit 3. The PMOS transistor MP7 is connected between a source of the PMOS transistor MP3 and the power supply VDD. The PMOS transistor MP8 is connected between a source of the PMOS transistor MP6 and the power supply VDD. The NMOS transistor MN8 is connected between a source of the NMOS transistor MN4 and the ground GND. The NMOS transistor MN9 is connected between a source of the NMOS transistor MN7 and the ground GND. Further, gates of the PMOS transistors MN4, MP5, MP7, and MP8 are connected to an output terminal M1 of the control circuit 3. Gates of the NMOS transistor MN5, MN6, MN8, and MN9 are connected to an output terminal M2 of the control circuit 3.

In the second embodiment, the control circuit 3 is a circuit for switching between a normal operation and a test operation of the comparator circuit. In this embodiment, the control circuit 3 specifies the output terminal M1 to be “L” level, and the output terminal M2 to be “L” level.

The test here indicates a test for measuring leakage current of a comparator circuit. To conduct such a test, a steady-state current flowing from the power supply VDD to the ground GND needs to be eliminated.

In the comparator circuit of the second embodiment when conducting such a test, the control circuit 3 outputs signals to turn off the PMOS transistors MP4, MP5, MP7, and MP8, and the NMOS transistors MN5, MN6, MN8, and MN9. This removes a steady-state current flowing the noise tracing unit. Accordingly it is possible to prevent a steady-state current from flowing and exerting an influence in measuring leakage current.

The control circuit 3 outputs signals (control signals) from the output terminals M1 and M2. Then the signal from M1 switches on/off (i.e. conductive/non-conductive) of the PMOS transistors MP4 and MP5, and the switching devices MP7 and MP8. The signal from M2 switches on/off (i.e. conductive/non-conductive) of the NMOS transistors MN5 and MN6, and the switching devices MN8 and MN9. In a normal operation, the PMOS transistors MP4, MP5, MP7, and MP8, and NMOS transistors MN5, MN6, MN8, and MN9 are all turned on (conductive). In a test operation the transistors are all turned off (non-conductive). It means that output levels of the M1 and M2 are reversed. Further, it is desirable that if the output levels of the M1 and M2 are “H”, the output levels equal to the power supply, and if the output levels are “L”, they equal to the ground of the comparator circuit. In FIG. 8 and the above mentioned example, an input of the comparator unit (i.e. gates of the MOS transistor MN1 and MN2) is a floating. However if necessary, a bias voltage to turn off the transistor MN3 may be applied in a test.

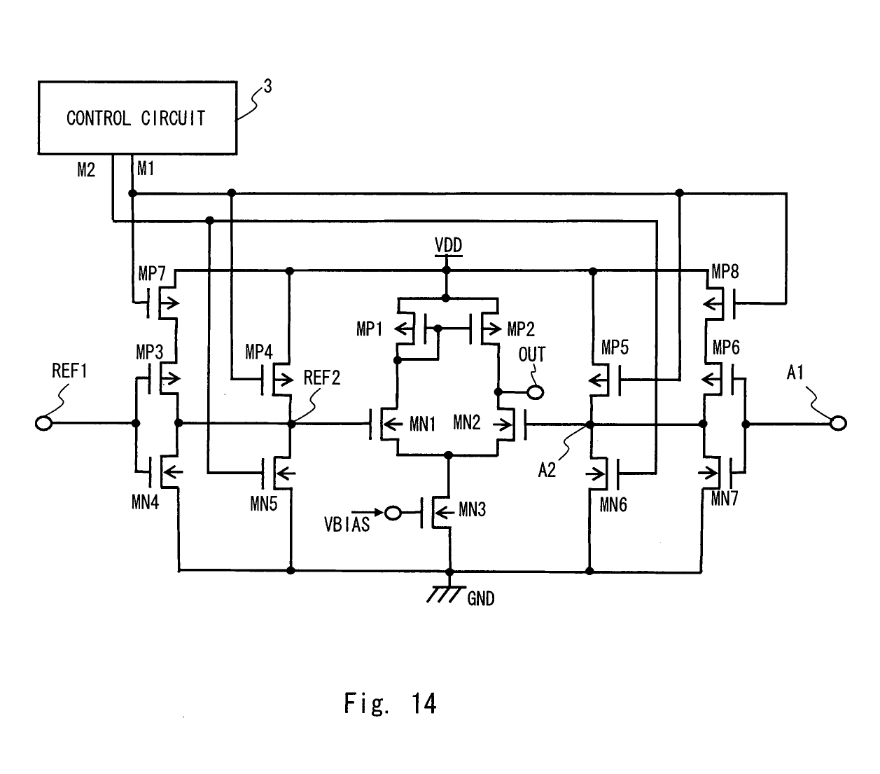

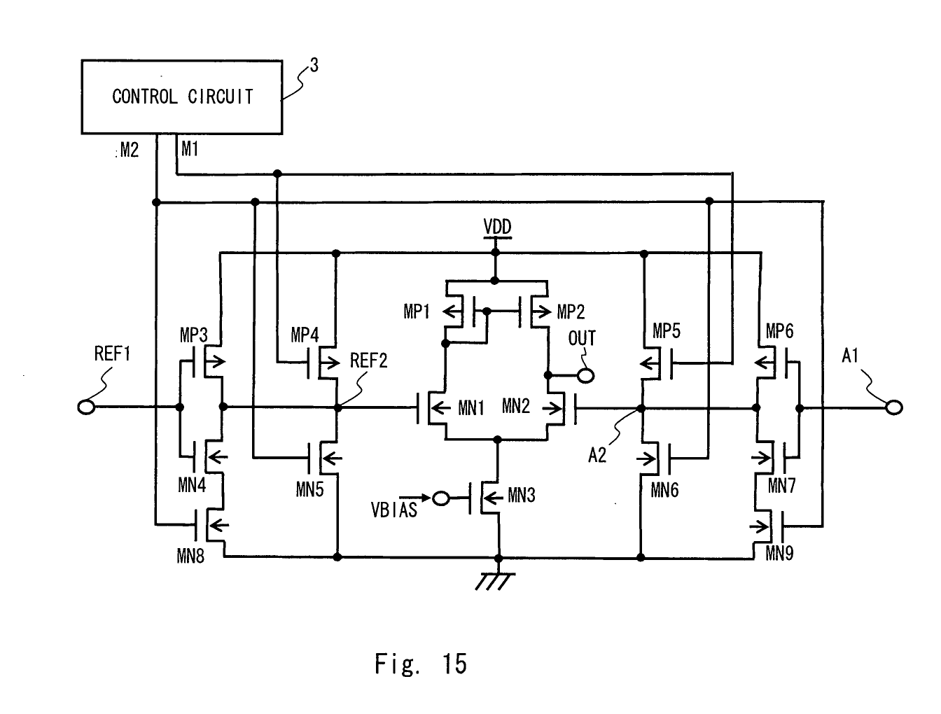

In the circuit of the second embodiment, the PMOS transistors MP7 and MP8 are provided closer to the power supply side than the input terminal REF1, and NMOS transistors MN8 and MN9 are provided closer to the ground side than the A1, and outputs signals to the output terminals M1 and M2 to turn off those transistors. However as shown in FIGS. 14 and 15, if a steady-state current can be prevented, the switches may be provided to either one of the power supply side or the ground side. For example a steady-state current can be blocked with a configuration where only the PMOS transistors MP7 and MP8 are added, gates of the PMOS transistors MP4, MP5, MP7, and MP8 are connected to the output terminal M1 of the control circuit 3, and gates of the NMOS transistors MN5 and MN6 are connected to the output terminal M2 (see FIG. 14). Alternatively a steady-state current can be blocked with a configuration where only the NMOS transistors MN8 and MN9 are added, gates of the PMOS transistors MP4 and MP5 are connected to the output terminal M1 of the control circuit 3, and gates of the NMOS transistors MN5, MN6, MN8 and MN9 are connected to the output terminal M2 (see FIG. 15).

A comparator circuit of the present invention is not restricted to an input circuit to be an interface of a semiconductor apparatus. The present invention can be applied to an input unit inside a semiconductor apparatus. For example in a case where both a logic and an analog circuits are mounted to a semiconductor apparatus, and a case where two circuits use different power supply voltage, power supply and ground are provided to each of the circuit. In such a semiconductor apparatus, since the power supply and the ground are separated, the power supply and the ground voltages may fluctuate by each separated region. In such a case, it is possible to prevent a delay fluctuation caused by a fluctuation in the power supply and the ground of a circuit receiving a signal by using the comparator circuit of the present invention to receive signals from circuit having different power supply and ground, even inside the semiconductor apparatus. Furthermore to design a semiconductor apparatus, a delay verification is performed in consideration of production tolerance variations. However the circuit of the present invention induces only a few delay fluctuation caused by production tolerance variation, thereby making a design easier.

As an analog circuit described in the foregoing, there are a PLL circuit and a reference voltage generation circuit. Especially for the reference voltage generation circuit, one or a small number of the reference voltage generation circuits are often mounted to a semiconductor apparatus to provide reference voltages to a plurality of comparator circuit etc. Those reference voltage generation circuits are mounted to a region isolated from the power supply and the ground as with the abovementioned case so as not to be influenced by noise of nearby circuits. A separate power supply (third power supply) and ground (fourth power supply) are supplied to the reference voltage generation circuit other than power supplies for other circuit in the semiconductor apparatus. The present invention is applicable to a case where the reference voltage VREF is supplied from such reference voltage generation circuits. The present invention is especially applicable to a case where a signal having less noise by the power supply and the ground is inputted to a comparator circuit, and the power supply and the ground of the comparator circuit fluctuates due to noise. In light of this, a reference voltage generation circuit placed to a region isolated from the power supply and the ground may be mounted to a comparator circuit of the present invention.

As described in the foregoing, the comparator circuit of this invention provides a noise tracing unit to enable a reference voltage and an input voltage to be compared to change reflecting fluctuations of the power supply. By comparing the voltages that changes reflecting the fluctuation in the power supply, it is possible to have a stable response time to a change in input voltage to be compared against. Further, by forming transistors comprising a differential input stage at the same time as the transistors of a noise tracing unit, it is possible to suppress a fluctuation in response time caused by production tolerance variations.

It is apparent that the present invention is not limited to the above embodiment and it may be modified and changed without departing from the scope and spirit of the invention.

What is claimed is:

1. A comparator circuit comprising:
a differential circuit having a transistor pair comprised of PMOS transistors or NMOS transistors with their sources connected to each other;
a first PMOS transistor having a source connected to a first power supply, a drain connected to a first node, and a gate connected to a reference voltage input terminal;
a first NMOS transistor having a source connected to a second power supply, a drain connected to the first node, and a gate connected to the reference voltage input terminal;
a second PMOS transistor having a source connected to the first power supply, a drain connected to the first node, and a gate applied with a voltage of the second power supply;
a second NMOS transistor having a source connected to the second power supply, a drain connected to the first node, and a gate applied with a voltage of the first power supply;
a third PMOS transistor having a source connected to the first power supply, a drain connected to a second node, and a gate connected to a signal input terminal;
a third NMOS transistor having a source connected to the second power supply, a drain connected to the second node, and a gate connected to a signal input terminal;
a fourth PMOS transistor having a source connected to the first power supply, a drain connected to the second node, and a gate applied with a voltage of the second power supply; and
a fourth NMOS transistor having a source connected to the second power supply, a drain connected to the second node, and a gate applied with a voltage of the first power supply,
wherein the first and the second power supplies are supplied to the differential circuit;
one of the transistors forming the transistor pair includes a gate connected to the first node, and another transistor forming the transistor pair includes a gate connected to the second node; and
the differential circuit outputs a comparison result between a voltage of a signal inputted to the signal input terminal and a reference voltage applied to the reference voltage input terminal as a comparison result between a voltage value of the first node and a voltage value of the second node.

2. The comparator circuit according to claim 1, wherein the transistors forming the transistor pair are formed on the same substrate which is a transistor of the same conductive type among the transistors included in the comparator circuit is formed.

3. The comparator circuit according to claim 1, further comprising a reference voltage generation circuit supplied with a third and a fourth power supply for generating the reference voltage, and the first power supply, the second power supply, the third power supply, and the fourth power supply are separated from each other.

4. The comparator circuit according to claim 1, further comprising:
a first switch device connected in series with the first PMOS transistor and the first NMOS transistor;
a second switch device connected in series with the third PMOS transistor and the third NMOS transistor; and
a control circuit for outputting one or a plurality of control signals,
wherein the control circuit exclusively controls a voltage applied to gates of the second PMOS transistor and the fourth PMOS transistor by the control signals and a voltage applied to gates of the second NMOS transistor and the fourth NMOS transistor by the control signals, and controls a conductive condition of the first and the second switch devices;
the second and the fourth PMOS transistors, and the second and the fourth NMOS transistors are turned on in a normal operation to make the first and the second switch devices conductive; and
the second and the fourth PMOS transistors, and the second and the fourth NMOS transistors are turned off to make the first and the second switching devices non-conductive.

5. A semiconductor apparatus having a reference voltage generation circuit and a comparator circuit comprising:
a differential circuit having a transistor pair comprised of PMOS transistors or NMOS transistors with their sources connected to each other;
a first PMOS transistor having a source connected to a first power supply, a drain connected to a first node, and a gate connected to a reference voltage input terminal;
a first NMOS transistor having a source connected to a second power supply, a drain connected to the first node, and a gate connected to the reference voltage input terminal;
a second PMOS transistor having a source connected to the first power supply, a drain connected to the first node, and a gate applied with a voltage of the second power supply;
a second NMOS transistor having a source connected to the second power supply, a drain connected to the first node, and a gate applied with a voltage of the first power supply;
a third PMOS transistor having a source connected to the first power supply, a drain connected to a second node, and a gate connected to a signal input terminal;
a third NMOS transistor having a source connected to the second power supply, a drain connected to the second node, and a gate connected to a signal input terminal;
a fourth PMOS transistor having a source connected to the first power supply, a drain connected to the second node, and a gate applied with a voltage of the second power supply; and
a fourth NMOS transistor having a source connected to the second power supply, a drain connected to the second node, and a gate applied with a voltage of the first power supply,
wherein the first and the second power supplies are supplied to the differential circuit of the comparator circuit;
one of the transistors forming the transistor pair includes a gate connected to the first node, and another transistor forming the transistor pair includes a gate connected to the second node;
the differential circuit outputs a comparison result between a voltage of a signal inputted to the signal input terminal and a reference voltage applied to the reference voltage input terminal as a comparison result between a voltage value of the first node and a voltage value of the second node; and
the reference voltage generation circuit operates on a third and a fourth power supply that are different from the first and the second power supplies.

6. The semiconductor apparatus according to claim 5, wherein the transistors forming the transistor pair are formed on the same substrate which is a transistor of the same conductive type among the transistors included in the comparator circuit is formed.

7. The semiconductor apparatus according to claim 5, wherein the comparator circuit further comprises:
a first switch device connected in series with the first PMOS transistor and the first NMOS transistor;
a second switch device connected in series with the third PMOS transistor and the third NMOS transistor; and
a control circuit for outputting one or a plurality of control signals,
wherein the control circuit exclusively controls a voltage applied to gates of the second PMOS transistor and the fourth PMOS transistor by the control signals and a voltage applied to gates of the second NMOS transistor and the fourth NMOS transistor by the control signals, and controls a conductive condition of the first and the second switch devices;
the second and the fourth PMOS transistors, and the second and the fourth NMOS transistors are turned on in a normal operation to make the first and the second switch devices conductive; and
the second and the fourth PMOS transistors, and the second and the fourth NMOS transistors are turned off to make the first and the second switching devices non-conductive.

8. A comparator circuit comprising:
a comparator unit connected between a first power supply and a second power supply;
a first noise tracing unit for inputting a first signal based on a first input signal to the comparator unit, and connected between the first power supply and the second power supply; and
a second noise tracing unit for inputting a second signal based on a second input signal to the comparator unit, and connected between the first power supply and the second power supply.

9. The comparator circuit according to claim 8, wherein the first noise tracing unit comprises;
a first inverter for amplifying the first input signal;
a first divider for dividing a first output signal of the first inverter and outputting the first signal; and
wherein the second noise tracing unit comprises;
a second inverter for amplifying the second input signal;
a second divider for dividing a second output signal of the second inverter and outputting the second signal.

10. The comparator circuit according to claim 9, wherein the first divider comprises a first MOS transistor and a second MOS transistor, and the second divider comprises a third MOS transistor and a fourth MOS transistor.

11. The comparator circuit according to claim 10, wherein the first MOS transistor and the second MOS transistor are connected in series between the first power supply and the second power supply, and the third MOS transistor and the fourth MOS transistor are connected in series between the first power supply and the second power supply.

12. The comparator circuit according to claim 11, wherein a first voltage is applied to gates of the first MOS transistor and the third MOS transistor, and a second voltage is applied to the second MOS transistor and the fourth MOS transistor.
